(19) United States
(12) Patent Application Publication
(10) Pub. No.: US 2019/0020341 A1
(43) Pub. Date: Jan. 17, 2019

(54) METHOD AND CIRCUIT STRUCTURE FOR SUPPRESSING SINGLE EVENT TRANSIENTS OR GLITCHES IN DIGITAL ELECTRONIC CIRCUITS

(71) Applicant: Nelson Mandela University, Port Elizabeth (ZA)

(72) Inventor: Farouk Smith, Port Elizabeth (ZA)

(73) Assignees: Nelson Mandela University, Port Elizabeth (ZA); Nelson Mandela University, Port Elizabeth (ZA)

(21) Appl. No.: 15/754,407

(22) PCT Filed: Sep. 11, 2017
(86) PCT No.: PCT/IB2017/055455

§ 371 Date: Feb. 22, 2018

(30) Foreign Application Priority Data
Sep. 12, 2016 (ZA) 2016/06283

(51) Int. Cl. H03K 19/003; H03K 19/007

(52) U.S. Cl. CPC H03K 19/00392; H03K 19/0075

(57) ABSTRACT

A circuit structure and a method for supressing single event transients (SETs) or glitches in digital electronic circuits are provided. The circuit includes a first input which receives an output of a digital electronic circuit and a second input which receives a redundant or duplicated output of the digital electronic circuit. The circuit includes only four two-input gates of two different kinds selected from AND, OR, NAND and NOR gates. The four two-input gates being arranged so that a final circuit output is impervious to a change in a logic level of only the first input or only the second input, and the final circuit output is equivalent to the logic level of the first and second inputs when the logic level of the first and second inputs match.

### CROSS-REFERENCE TO RELATED APPLICATIONS

This application claims priority from South African provisional patent application number 2016/06283 filed on 12 Sep. 2016, which is incorporated by reference herein.

### FIELD OF THE INVENTION

The invention relates to a method and a circuit structure for suppressing single event transients (SETs) or single event upsets (SEUs) in digital electronic circuits. The invention finds particular but by no means exclusive application in mitigating SETs and SEUs in combinational circuits which form part of sequential electronic circuits, such as Field Programmable Gate Arrays (FPGAs) and Application Specific Integrated Circuits (ASICs).

### BACKGROUND TO THE INVENTION

The use of field programmable gate arrays (FPGAs) for space-based computing operations is widespread. FPGAs are generally computationally slower than their Application Specific Integrated Circuit (ASIC) counterparts, cannot handle as complex a design and draw more power than ASICs. However, FPGAs do offer several important advantages. These include a shorter time to market, the ability to re-program the device and lower engineering costs. Since these features are particularly advantageous for spacecraft applications, the space community has actively evaluated radiation effects for most new FPGAs being introduced. Unfortunately, while FPGAs offer several benefits for space-based electronics, they are generally sensitive to Single Event Effects (SEEs).

SEEs are caused by ionization as a consequence of the impact of a heavy ion (cosmic ray) or proton. The ionization induces a current pulse in a p-n junction. Single Event Effects include those effects which permanently damage circuitry, such as Single Event Latch-Up (SEL), Single Event Gate Rupture (SEGR), or Single Event Burnout (SEB), as well as “soft errors” referred to as Single Event Transients (SETs), which do not permanently damage circuitry.

SETs are caused by charged particles depositing charge on circuit elements through ionization. These deposited charges cause elevated local voltage levels in the circuit elements, which can non-destructively change the state of a bi-stable element. In a combinational logic element, the charge will leak away (typically over several hundreds of picoseconds) and the element will return to the correct state. However, when synchronous logic is disturbed by an SET on a clock edge, the temporarily incorrect logic value is latched into the register. This incorrect value can then propagate though the rest of the circuit. SETs that are latched into a register are called Single Event Upsets (SEUs).

In a satellite computer, for example, a bit-flip caused by an SEU could randomly change critical data, randomly change program data, or randomly change a register value. The changes can cause the software to perform unintended commands and thus cause the software to “crash”.

SEUs in an FPGA may affect the user design flip-flops, the FPGA configuration memory, as well as any hidden FPGA registers, latches, or internal state. Configuration memory upsets are especially problematic because such upsets affect both the state and operation of the design. Configuration upsets may perturb the routing resources and logic functions in a way that changes the operation of the circuit. The effects of single event upsets in the device configuration memory are not limited to modifications in the memory elements, but they may also produce modifications in the interconnections inside Configurable Logic Blocks (CLB) and among different CLBs, thus giving rise to totally different circuits from those intended.

Flash and Antifuse FPGAs have configuration memories that are insensitive to SETs, and any SET present in the user logic will be temporary. However, in FPGAs with volatile memories, in particular in SRAM based FPGAs, the major contributor of errors caused by SETs is due to configuration memory errors. Configuration memory errors in SRAM based FPGAs do not dissipate, but persist until a power reset loads new configuration memory on the FPGA or a scheduled configuration memory reset occurs. SEUs can become Single Event Functional Interrupts (SEFI) when they upset control circuits, such as state machines, placing the device into an undefined state, a test mode, or a halt, which would then need a reset or a power cycle to recover.

From the above it is apparent that some kind of single event upset mitigation scheme is crucial for the successful deployment of FPGAs and even ASICs for space-based applications. Single event upset mitigation can also be important for safety-critical terrestrial applications.

Double Modular Redundancy (DMR) SEU mitigation solutions rely on duplication of the combinational circuit and a comparison of the outputs of the duplicated circuits. Most DMR solutions, however, are only generally able to detect SEUs but not mask or correct them.

The most common mitigation scheme for correcting SEU errors in sequential circuits in orbit is Triple Modular Redundancy (TMR) plus scrubbing. TMR is a spatial redundancy technique that compares three signal values by means of a voting circuit, where the output is equal to the two inputs that agree. Any single event upsets will be removed through scrubbing and the bad state will either be masked or fixed by the triple modular redundancy (depending on the implementation). TMR is often exploited for hardening digital logic against single event upsets in safety-critical applications. As an instance, TMR is often exploited to design fault-tolerant memory elements to be employed in sequential digital logic. The main disadvantage of TMR is the excessive area overhead. The hardened design, with triplication of the combinational circuit and additional voting circuitry, can have between 4 and 7 times more area and power consumption than the original circuit, which limits its usage to reliability-critical applications.

Radiation tolerant FPGAs for space and military applications are available, but these tend to be orders of magnitude more expensive than their off-the-shelf counterparts. Furthermore, while radiation tolerant FPGAs or non-volatile FPGAs or ASICS are capable of masking the effects of single event upsets in the configuration memory, triple modular redundancy is generally still required in the user logic circuitry for critical applications.

In the applicant's own PCT publication number WO2011/121414, a method and circuit for mitigating SEUs is presented which relies on double modular redundancy and a voter circuit between each pair of outputs, where the voter circuit is able to indicate the presence of an SEU if the two outputs are not identical. The voter outputs are all compared by a multiple input voter circuit and, if any one or more of the voter outputs indicates the presence of an SEU, the state memory latch elements (such as flip-flops) are all disabled until the presence of the single event upset has disappeared. In this way, the circuit “freezes” for the duration of the single event upset. While this method is effective in mitigating SEUs, the voters require a significant amount of additional circuitry and complexity, double modular redundancy is still required, and a small additional delay is introduced during the time in which the circuit is “frozen”. Furthermore, configuration memory errors are identified by detecting that the circuit has remained frozen for more than a predetermined time period and then reconfiguring the configuration memory. This wait time introduces much longer time delays in the case of configuration memory errors.

In a further PCT application of the applicant, publication number WO2013057707, a circuit structure for suppressing single event transients (SETs) or glitches in digital electronic is presented that relies on a multiplexer arrangement wherein the multiplexer input is determined by the logic value of the output of the multiplexer and two sub-circuits that are arranged such that the output of the sub-circuit which is insensitive to a change in the value of one of the inputs is selected whenever the output of the multiplexer changes.

The so-called Muller C-element is a circuit element that may be used for the suppression of SETs. The Muller C-element is defined by the equation:

yₙ=x₁·x₂+(x₁·yₙ₋₁)+(x₂·yₙ₋₁) Equation 1: Muller C-element logic equation

where x₁ and x₂ are the respective inputs to the C-element and y is its output.

A logical implementation of the above Muller C-element equation above requires 5 logic operations that each require two inputs, namely two AND operations and three OR operations. The applicant believes there is scope for improvement.

The preceding discussion of the background to the invention is intended only to facilitate an understanding of the present invention. It should be appreciated that the discussion is not an acknowledgment or admission that any of the material referred to was part of the common general knowledge in the art as at the priority date of the application.

### SUMMARY OF THE INVENTION

In accordance with the invention there is provided a circuit structure for supressing single event transients (SETs) or glitches in digital electronic circuits, comprising:
a first input which receives an output of a digital electronic circuit;
a second input which receives a redundant or duplicated output of the digital electronic circuit; and
only four two-input gates of two different kinds selected from AND, OR, NAND and NOR gates, the four two-input gates being arranged so that a final circuit output is impervious to a change in a logic level of only the first input or only the second input, and the final circuit output is equivalent to the logic level of the first and second inputs when the logic level of the first and second inputs match.

In one embodiment, the four two-input gates consist of two AND gates and two OR gates, a first AND gate and a first OR gate both receiving as inputs the first and second inputs, the first OR gate having a first output as its output and the first AND gate having a second output as its output, a second AND gate receiving as its inputs the first output and the final output of the circuit and having a third output as its output, and a second OR gate having as its inputs the second output and third output and having the final circuit output as its output.

Alternative features provides for the four two-input gates to include three inverting gates and one non-inverting gate.

Further features provide for the three inverting gates to be NAND gates and the non-inverting gate to be an OR gate, the OR gate receiving the first and second inputs and having a first output, a first NAND gate receiving the first and second inputs and having a second output, the second NAND gate receiving the first output and the final circuit output and having a third output, and the third NAND gate receiving the second output and the third output and having the final circuit output as its output.

Yet further alternative features provide for the three inverting gates to consist of two NAND gates and one NOR gate and for the non-inverting gate to be an OR gate, a first NAND gate and the NOR gate both receiving as inputs the first input and a final circuit output, the first NAND gate having a first output as its output and the NOR gate having a second output as its output, the OR gate receiving as inputs the second output and an inverted second input and having a third output as its output, and a second NAND gate receiving as inputs the first output and third output and having the final circuit output as its output.

The invention extends to a method of suppressing single event transients (SETs) or glitches in digital electronic circuits, comprising:
taking an output of a digital electronic circuit as a first input;
taking a redundant or duplicated output of the digital electronic circuit as a second input;
inputting the first input and second input into a logical circuit structure comprising only four two-input gates of two different kinds selected from AND, OR, NAND and NOR gates, the four two-input gates being arranged so that a final circuit output is impervious to a change in a logic level of only the first input or only the second input, and the final circuit output is equivalent to the logic level of the first and second inputs when the logic level of the first and second inputs match.

In one embodiment, the method includes the steps of:
inputting the first and second inputs into a first AND gate;
inputting the first and second inputs into a first OR gate;
taking an output of the first OR gate and a final circuit output and inputting them into a second AND gate;
taking the output of the second AND gate and an output of the first OR gate and inputting them into a second OR gate; and
taking the output of the second OR gate as the final circuit output.

In an alternative embodiment, the method includes the steps of:
inputting the first and second inputs into a first NAND gate;
inputting the first and second inputs into an OR gate;
taking an output of the OR gate and a final circuit output and inputting them into a second NAND gate;
taking an output of the second NAND gate and an output of the first NAND gate and inputting them into a third NAND gate; and
taking an output of the third NAND gate as the final circuit output.

In a further alternative embodiment, the method includes the steps of:
inputting the first input and the final circuit output into a NOR gate;
inputting the first input and the final circuit output into a first NAND gate;
inverting the second input;
taking the output of the NOR gate and the inverted second input and inputting them into an OR gate;
taking an output of the first NAND gate and an output of the OR gate and inputting them into a second NAND gate; and
taking the output of the second NAND gate as the final circuit output.

An embodiment of the invention will now be described, by way of example only, with reference to the accompanying drawings.

### BRIEF DESCRIPTION OF THE DRAWINGS

In the drawings:

FIG. 1A is a schematic representation of a first embodiment of a C-element in accordance with this invention;

FIG. 1B show a simulated timing diagram of the logic levels in the circuit structure of FIG. 1A;

FIG. 2 is a schematic representation of a second embodiment of a C-element in accordance with this invention;

FIG. 3 is a schematic representation of a third embodiment of a C-element in accordance with this invention;

FIG. 4 is a schematic representation of a first test circuit used for experimental verification;

FIG. 5 is a schematic representation of a second test circuit used for experimental verification;

FIG. 6 is a schematic representation of a third test circuit used for experimental verification;

FIG. 7 is a schematic representation of a fourth test circuit used for experimental verification;

FIG. 8 is a schematic representation of a fifth test circuit used for experimental verification;

FIG. 9 is a schematic representation of a sixth test circuit used for experimental verification;

FIG. 10 is a schematic representation of a seventh test circuit used for experimental verification; and

FIG. 11 is a flow diagram of a method of suppressing single event transients (SETs) or glitches in digital electronic circuits.

### DETAILED DESCRIPTION WITH REFERENCE TO THE DRAWINGS

Embodiments of the invention describe a circuit structure and a method for supressing single event transients (SETs) or glitches in digital electronic circuits. The circuit structure is generally a two-input, one-output configuration in which the output is an SET-suppressed signal in respect of the two inputs. The first input receives an output of a preceding digital electronic circuit and the second input receives a redundant or duplicated output of the preceding digital electronic circuit.

The components of the circuit structure include a total of four two-input gates selected from AND, OR, NAND and NOR gates. The four two-input gates are arranged so that the output is impervious to a change in a logic level of only the first input or only the second input. The output is equivalent to the logic level of the first and second inputs when the logic level of the first and second inputs match. It is necessary to emphasise that the logic equation shown in Equation 1 above requires 5 logic operations that each require two inputs, namely two AND operations and three OR operations.

The circuit structure may include a feedback signal at an input of one or more of the four two-input gates, and one or more one-input inverter or NOT gates at either or both of the inputs and/or the output of one or more of the four two-input gates, as will be described below.

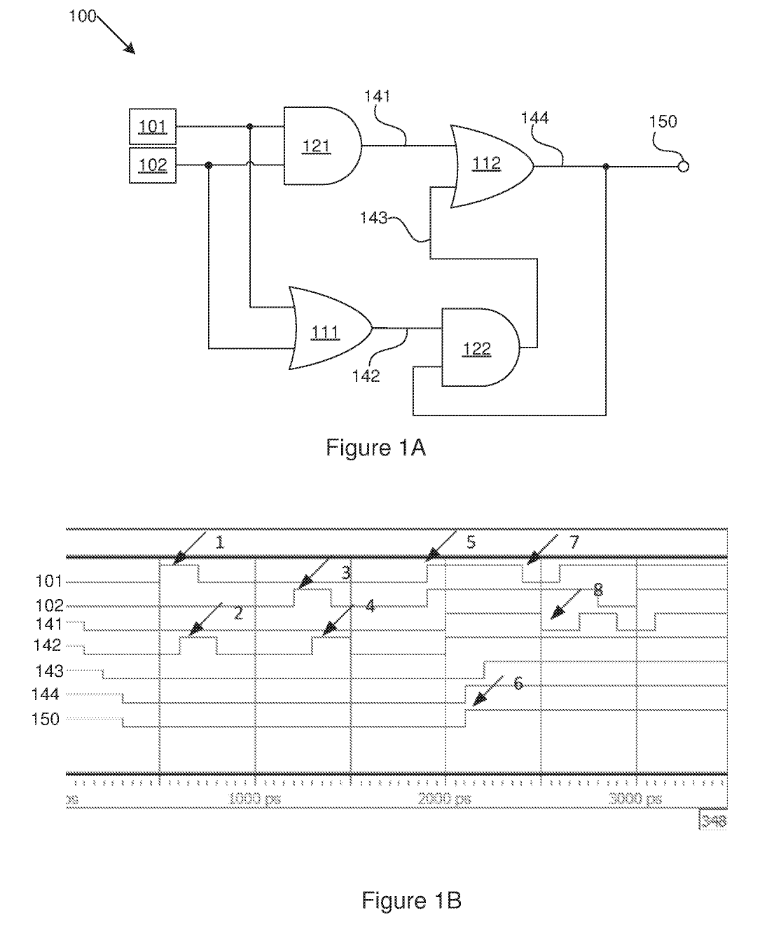

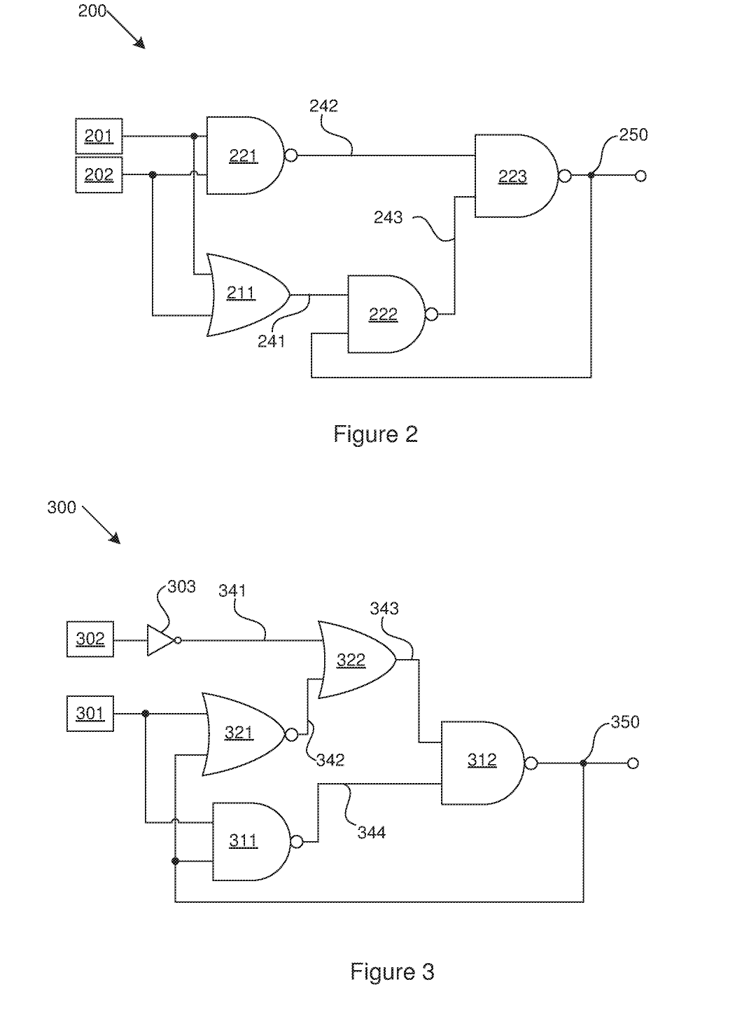

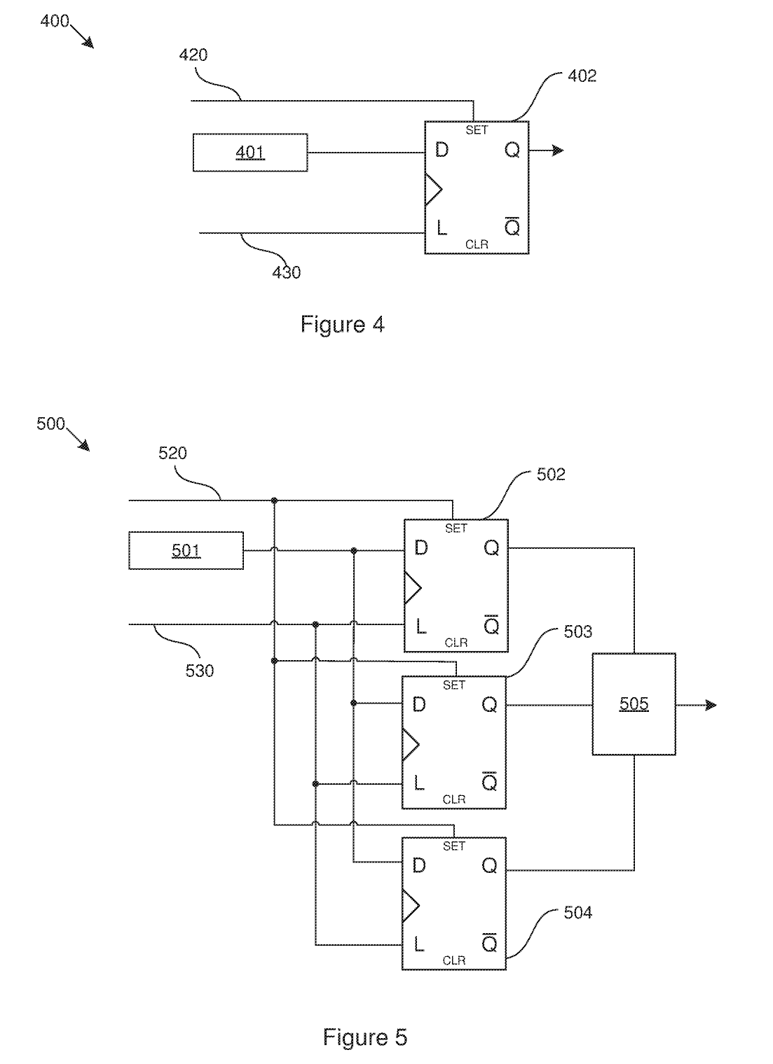

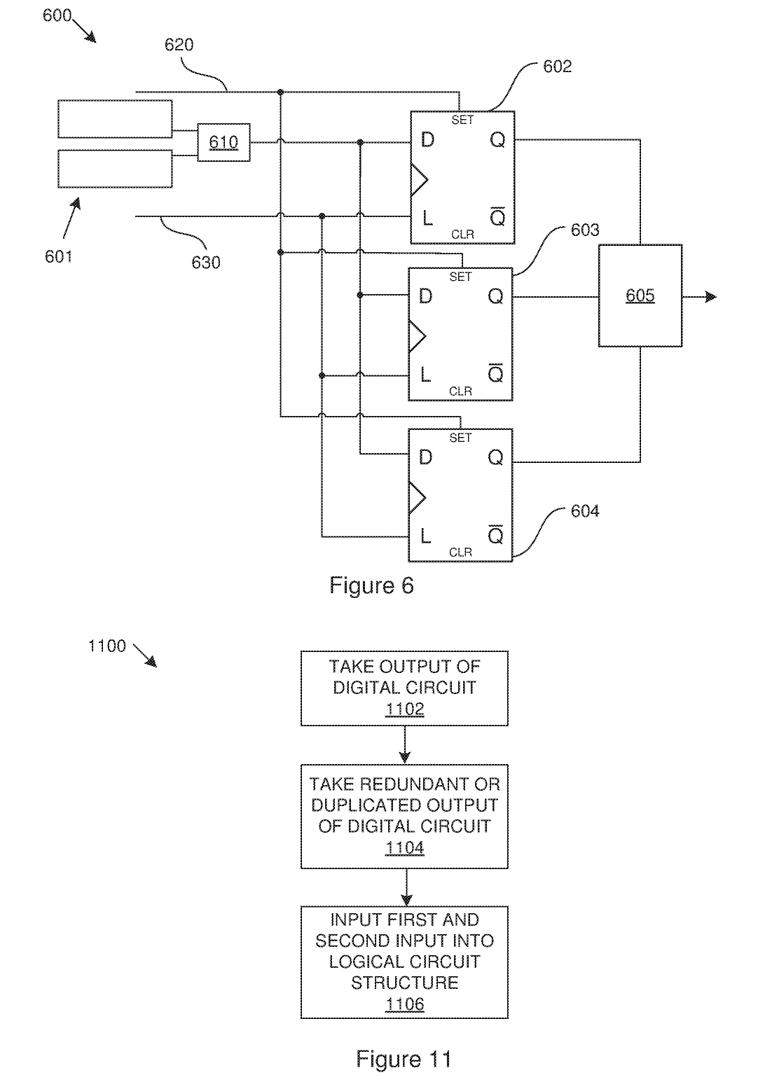

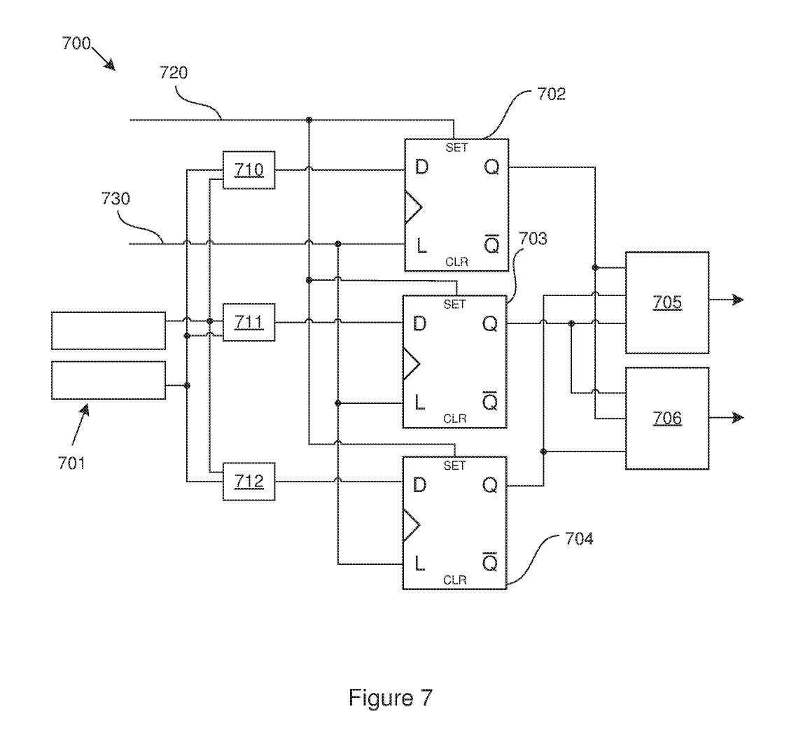

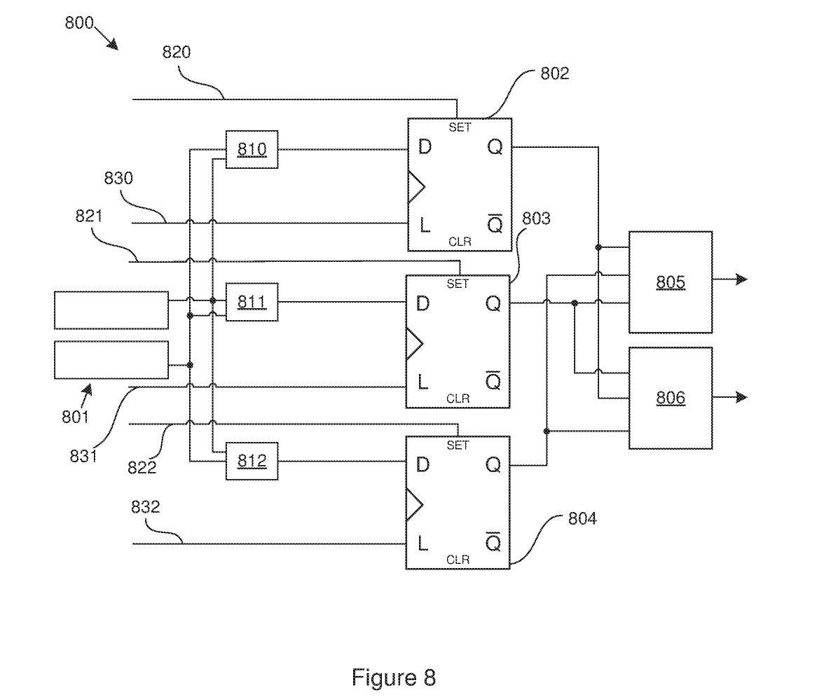

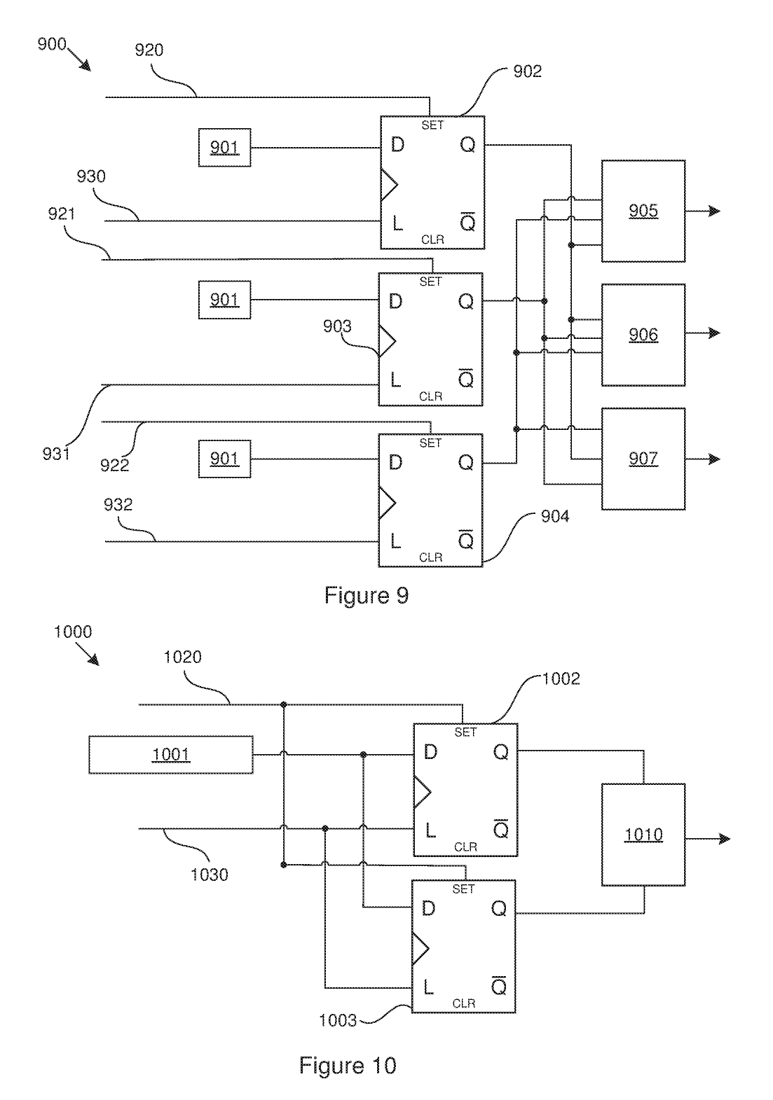

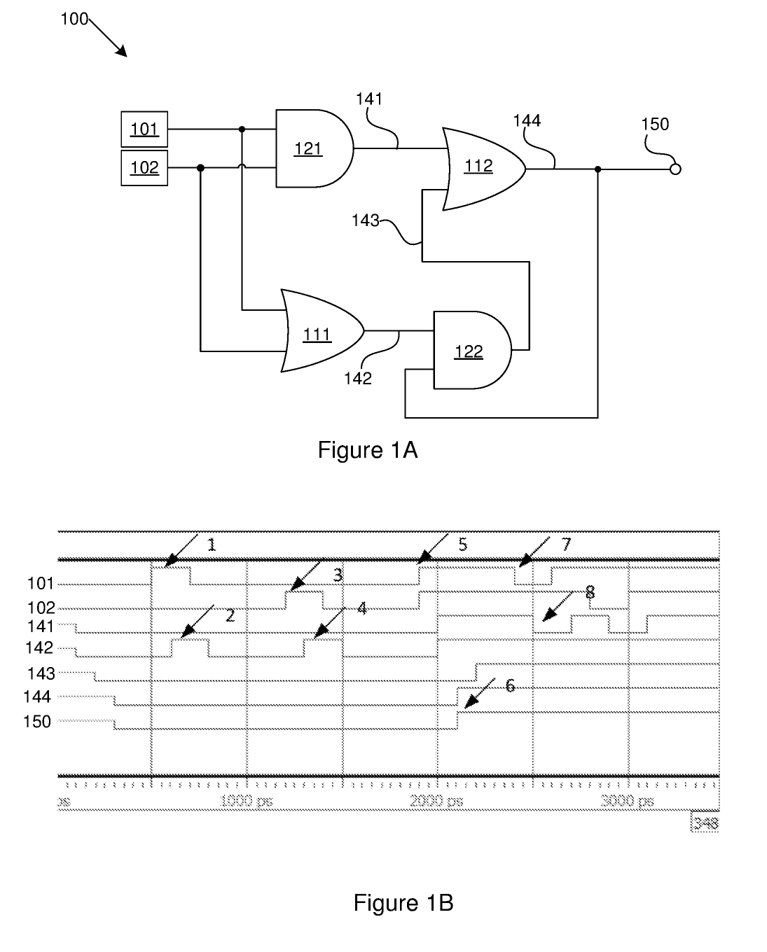

A first embodiment of a circuit (100) having a structure configured to suppress SETs or glitches in digital electronic circuits is shown in FIG. 1. The terminals of the circuit (100) include a first input (101), a second input (102) and a final circuit output (150). The first input (101) and second input (102) are configured to respectively receive an output of a preceding circuit or sub-circuit and a redundant or duplicate instance thereof.

The four two-input gates in this embodiment consist of two OR gates (111, 112) and two AND gates (121, 122).

A first OR gate (111) and a first AND gate (121) both receive, as inputs, the first and second inputs (101, 102) of the circuit. A second OR gate (112) receives, as one of its inputs, the output (141) of the first AND gate (121).

A second AND gate (122) receives, as one of its inputs, the output (142) of the first OR gate (111). The second AND gate (122) furthermore receives, as its second input, a feedback signal of the final output (150) of the circuit (100). An output (143) of the second AND gate (122) is, in turn, received as the second input of the second OR gate (112). The output (144) of the second OR gate (112) produces the final output (150) of the circuit (100).

The circuit (100) may be defined by the following equation:

yₙ=x₁·x₂+(x₁+x₂)·yₙ₋₁ Equation 2:Logic equation of first embodiment

where x₁ and x₂ are the first and second inputs of the circuit, respectively and y is the output of the circuit. It will be appreciated that this equation requires only four logic operations which each require two inputs. Therefore, there is a 20% reduction in the number of two-input logic gates required to implement this logic equation in hardware than that of Equation 1. This may save resources such as reduced power consumption and a reduction in required physical space.

FIG. 1B shows a simulated timing diagram of the logic levels in the circuit structure of FIG. 1A. At callout 1, an SET is induced with a length of 200 ps in the first input (101), resulting in the signal 142 changing to logic 1, as expected. However, since the final circuit output (150) is logic 0, the SET is prevented from filtering through to signal 143 at the output of the second AND gate (122). Thus, no SET effect is seen at the final circuit output (150). At callout 3, an SET is induced in the second input (102), with the output remaining stable, as before. At callout 7 and 8, with both the first input (101) and second input (102) at logic 1, an SET is again induced in the first input (101) and second input (102) respectively, with the final circuit output (150) remaining stable. The final circuit output will therefore always be insensitive to single bit flips that result from SETs at its input, irrespective of the current output logic level.

It will be appreciated that AND an OR logic gates may be internally implemented by transistors, generally Field Effect Transistors (FETs) and, more specifically, Complementary metal-oxide-semiconductor (CMOS) FET configurations. Typically, in respect of CMOS logic gates, a non-inverting OR gate and a non-inverting AND gate require at least 6 transistors for its implementation. In contrast therewith, their respective inverting counterparts, being NOR and NAND gates, require only 4 transistors for their implementation. It may therefore be more advantageous to implement an embodiment wherein the use of inverting gates is maximised, thereby minimising the total transistor count of the circuit and minimising gate delay times.

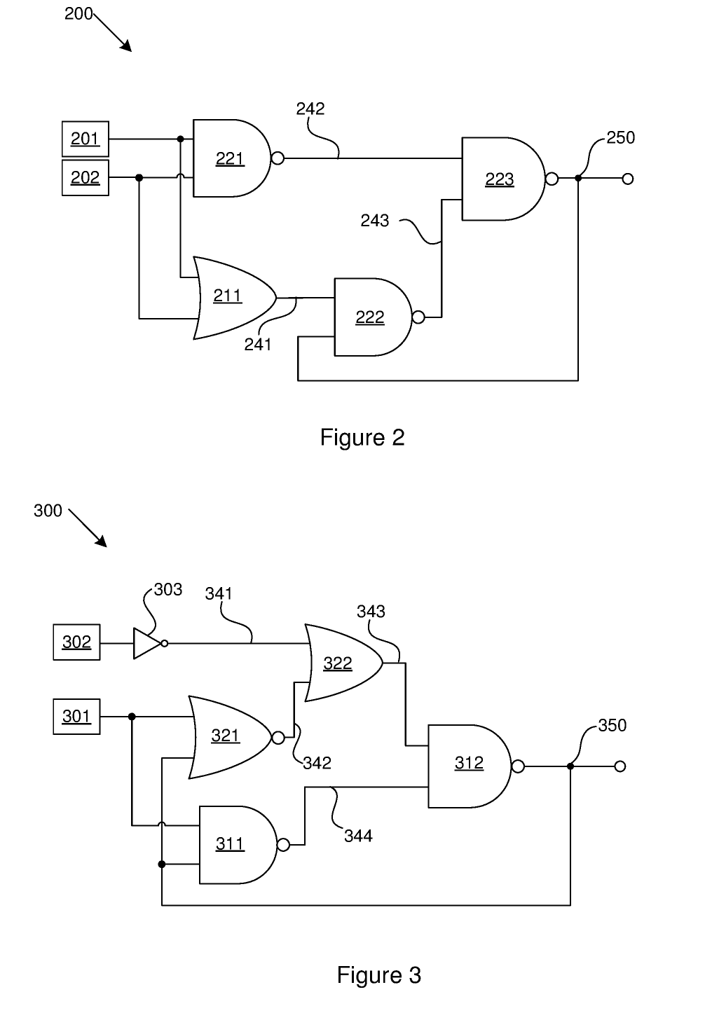

Such a circuit is shown in FIG. 2. In this second embodiment of the invention, the circuit (200) also includes four two-input logic gates of which three are inverting AND (i.e. NAND) gates (221, 222, 223) and one is a non-inverting OR gate (211).

The terminals of the circuit (200) again include a first input (201), a second input (202) and a final output (250). The first input (201) and second input (202) are configured to respectively receive an output of a preceding circuit or sub-circuit and a redundant or duplicate instance thereof.

The OR gate (211) and a first NAND gate (221) both receive, as inputs, the first and second inputs (201, 202) of the circuit. A second NAND gate (222) receives, as one of its inputs, the output (241) of the OR gate (211) and, as its second input, a feedback signal of the final output (250) of the circuit (200).

A third NAND gate (223) receives, as one of its inputs, the output (242) of the first NAND gate (221) and, as its second input, the output (243) of the second NAND gate (222). The output (244) of the third NAND gate (223) produces the final output (250) of the circuit (200).

The circuit (200) may be defined by the following equation:

yₙ=(̅x̅₁̅·̅x̅₂̅)̅·̅[̅(̅x̅₁̅+̅x̅₂̅)̅·̅y̅ₙ̅₋̅₁̅]̅ Equation 3:Logic equation of second embodiment

where x₁ and x₂ are the first and second inputs of the circuit, respectively and y is the output of the circuit. It will be appreciated that by transforming Equation 3 through the application of De Morgan's theorem, Equation 3 produces the same result as Equation 2.

Furthermore, the total transistor count of the circuit of the second embodiment (200) is less than that in the first embodiment (100). As stated above, at least six transistors are required to implement a non-inverting gate, whilst only four transistors are required for their inverting counterparts. Therefore, the circuit (200) of the second embodiment requires 18 transistors versus the 24 transistors required for the circuit (100) in the first embodiment.

A third embodiment of the invention is shown in FIG. 3, the circuit (300) of which also includes four two-input logic gates, i.e. two NAND gates (311, 312), one NOR gate (321) and one OR gates (322). Three of the two-input logic gates are therefore inverting gates, while one of the two-input logic gates is a non-inverting gate.

The terminals of the circuit (300) again include a first input (301), a second input (302) and a final circuit output (350). The first input (301) and second input (302) are configured to respectively receive an output of a preceding circuit or sub-circuit and a redundant or duplicate instance thereof.

The NOR gate (321) and a first NAND gate (311) both receive, as inputs, the first input (301) and a feedback of the final output (350) of the circuit (300). The second input (302) is inverted by a one-input NOT gate (303). This inverted signal (341) together with the output (342) of the NOR gate (321) are the inputs to the OR gate (322).

The output (343) of the OR gate (322) and the output (344) of the NAND gate (311) are provided as the two inputs of a second NAND gate (312). The output of this second NAND gate (312) provides the final output (350) of the circuit (300).

The circuit (300) may be defined by the following equation:

yₙ=(̅x̅₂̅·̅y̅ₙ̅₋̅₁̅)̅·̅[̅(̅x̅₂̅+̅y̅ₙ̅₋̅₁̅)̅·̅x̅ₓ̅]̅ Equation 4: Logic equation of third embodiment

where x₁ and x₂ are the first and second inputs of the circuit, respectively and y is the output of the circuit. It will again be appreciated that, by transforming Equation 4 through the application of De Morgan's theorem, Equation 4 produces the same result as Equation 2 and therefore also Equation 3.

Furthermore, although this embodiment includes an additional NOT gate (303), this NOT gate (303) is a single input gate. Therefore, the circuit still only includes four two-input logic gates.

Circuit structures of the invention may be used at the outputs of memory elements in order to mitigate SETs. Embodiments may furthermore be used at the output of memory elements in order to mitigate SEUs in a double modular redundancy formation, since the output will only change when there is a change in logic value at both memory elements.

### Experimental Results

Proton beam tests were performed at the separated-sector cyclotron (SSC) facility using an A-Line scattering chamber at iThemba Labs in Cape Town, South Africa. A single proton energy of 66 MeV was used for testing and validating the SET and SEU supressing capabilities of certain embodiments of the invention. Energies close to 60 MeV are considered effective for testing purposes as the distribution of proton energies above and below 60 MeV is equal in space.

Several sequential circuit designs were tested using the Microsemi™ ProASIC3E FPGA device with an M1A3PE1500 Cortex-M1 core in a PQ208 package as the device under test (DUT). The circuits were synthesized with the Synplify Pro™ E-2010 FPGA synthesis software. All designs were physically mapped onto the DUT using the Microsemi™ Place and Route Designer V.91 SP3.

The resources of the DUT as well as the control and monitoring board enabled the realisation of several designs simultaneously on the same FPGA whilst operating autonomously from one other. These designs consisted of seven sub-designs, Test circuits 1 to 7, with Test circuit 1 configured as the unmitigated circuit, and Test circuits 2 to 7 configured with various combinations of mitigation using the first embodiment described above as well as the conventional TMR majority voter.

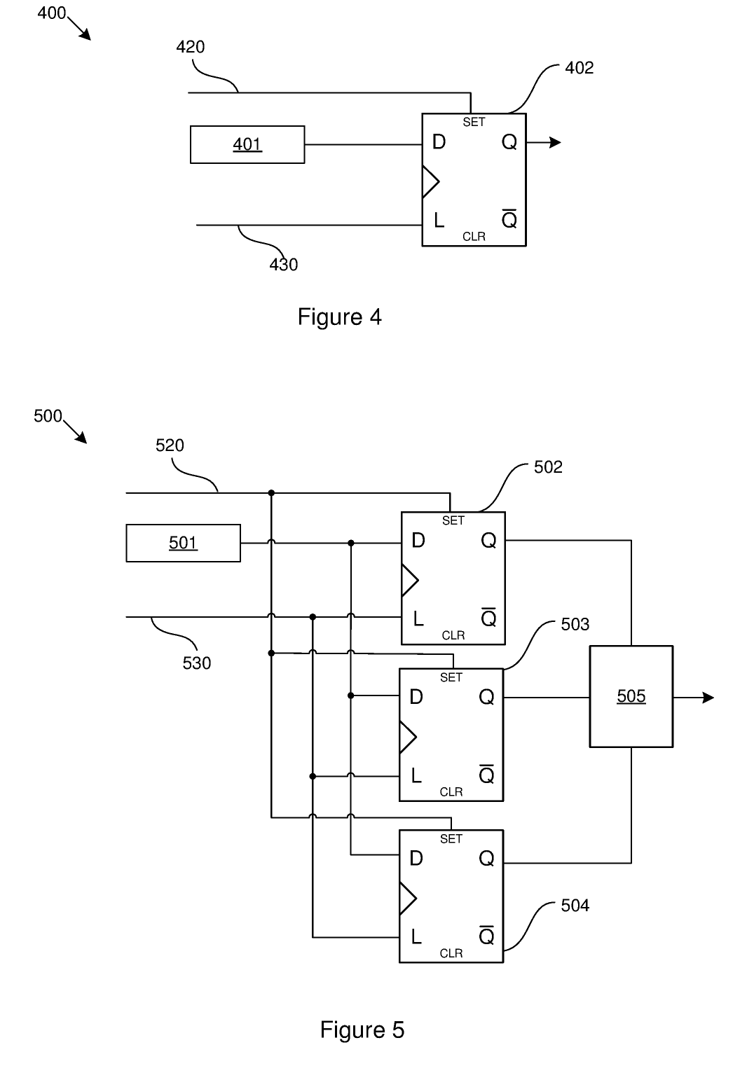

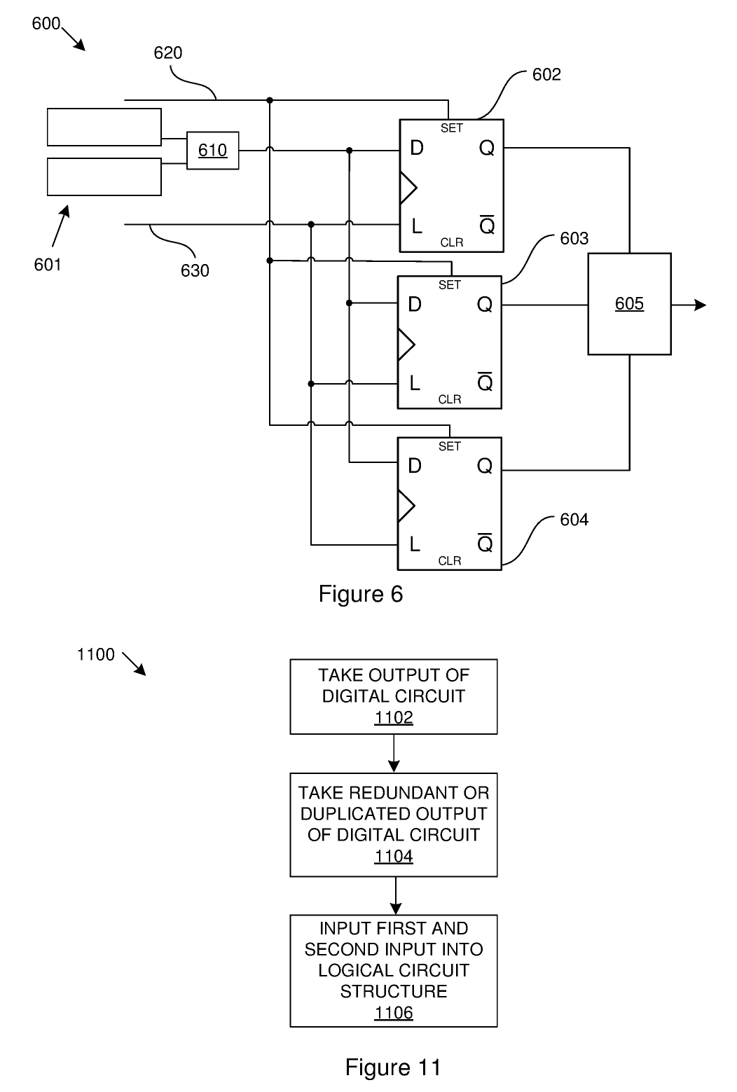

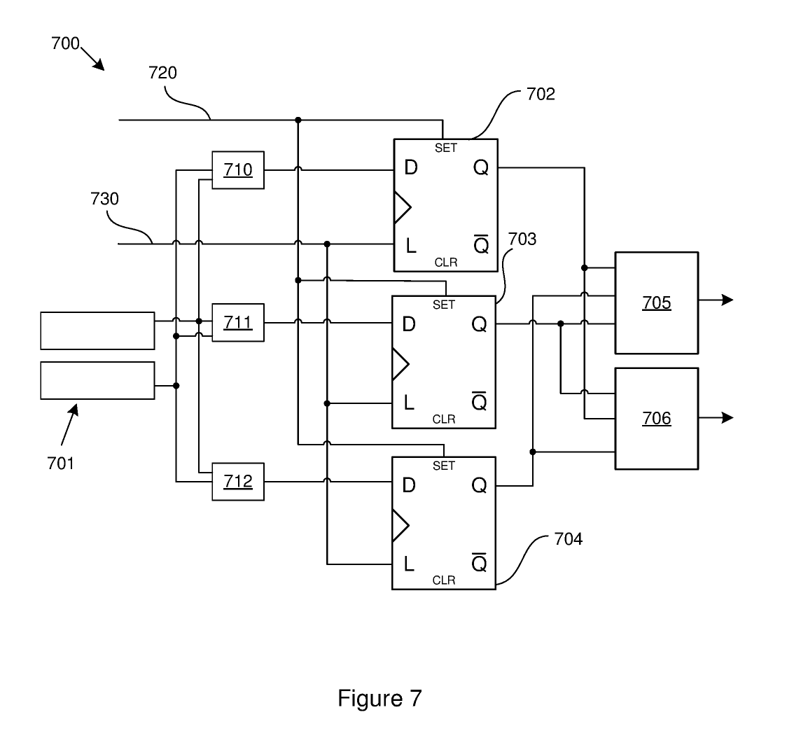

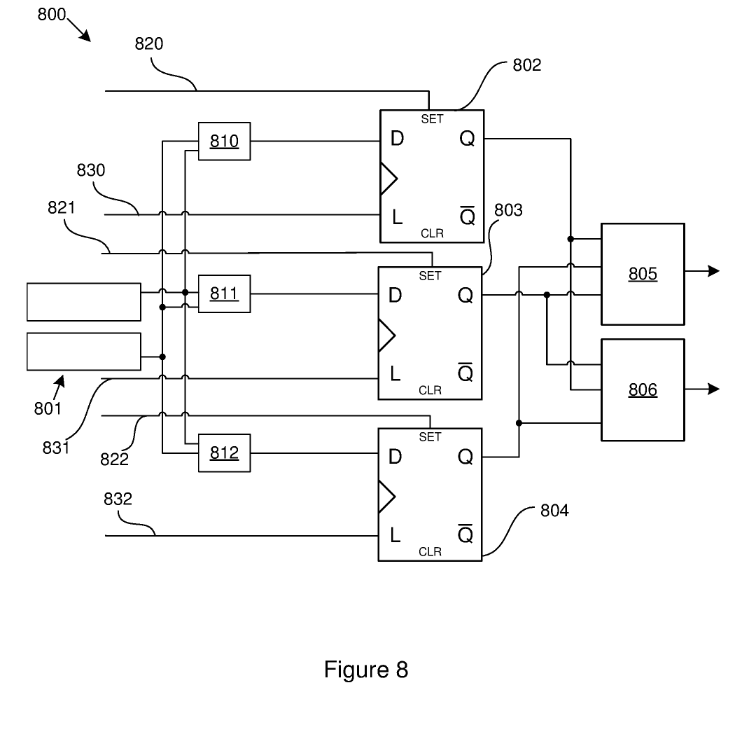

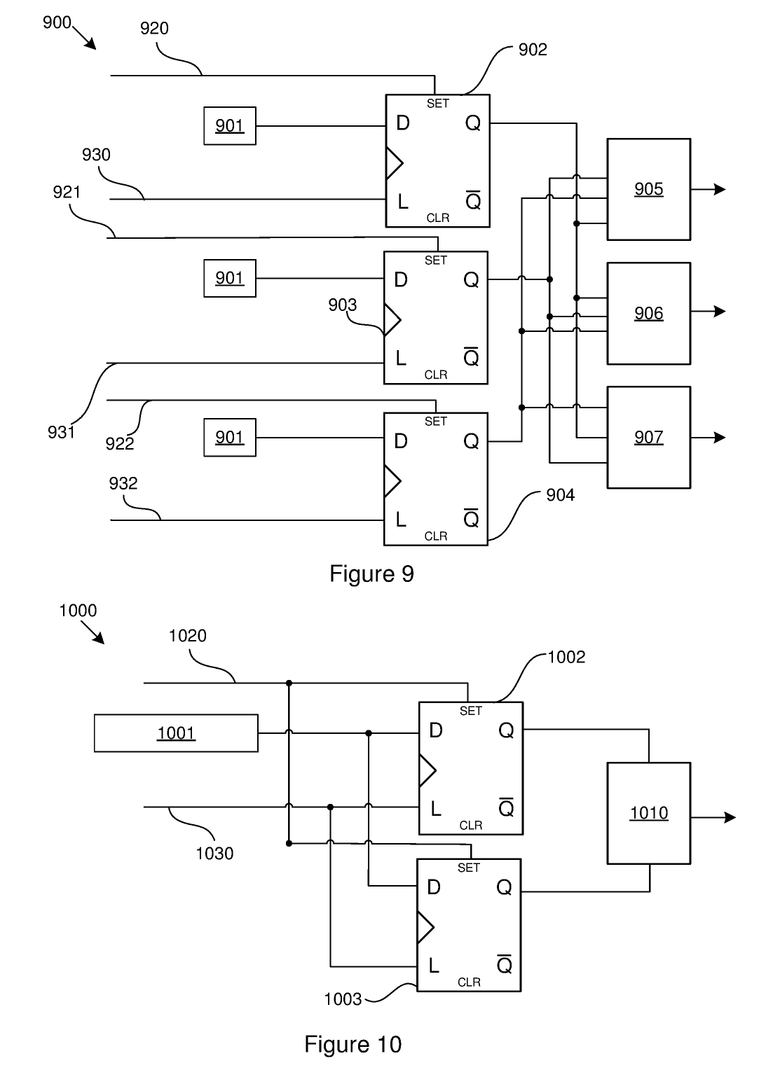

Each circuit implementation, as illustrated in FIGS. 4 to 10, was synthesised in triplicate and their respective outputs compared by a controller board. Any difference between outputs was counted as an SEU.

Test circuit 1 (400) was used as a control test and consisted of 64 shift register circuits (401) connected in series and having no SEU supressing circuitry and a latch (402) with a reset (420) and a latch (430) signal.

Test circuit 2 (500) consisted of 64 shift register circuits (501) connected in series without SEU protection of the combinational logic, but with local TMR provided for the latches (502, 503, 504), having common reset (520) and latch (530) signals, and having 1 majority voter (505).

Test circuit 3 (600) consisted of 64 shift register circuits connected in series with DMR protection of the combinational logic (601). Test circuit 3 (600) furthermore included one SET suppression circuit (610) interposed between the combinational logic (601) and a local TMR provided for the latches (602, 603, 604), having common reset (620) and latch (630) signals, and having 1 majority voter (605).

Test circuit 4 (700) consisted of 64 shift register circuits connected in series with DMR protection of the combinational logic (701). SET supressing circuits (710, 711, 712) are inserted before each latch (702, 703, 704), having common reset (720) and latch (730) signals, and local TMR with 2 majority voters (705, 706) provided for input to the next stage of the DMR user logic.

Test circuit 5 (800) is a copy of Test circuit 4 (700) with the modification that the reset (820, 821, 822) and latch (830, 831, 832) signals being triplicated.

Test circuit 6 (900) is an implementation of full triple modular redundancy.

Test circuit 7 (1000) consists of 64 shift register circuits (not shown) connected in series with DMR protection of the latches (1002, 1003). An SEU suppression circuit (1010) is inserted after the latches (1002, 1003).

During testing, each test circuit's inputs were loaded with a checker board data format at 10 kHz.

Each test circuit was written in VHDL and used as structural components in the combined design. An algorithm for generating the VHDL netlist of the complete design was then coded in the C++ language. The algorithm facilitated the specification of the number of test circuit replicas to fill close to 100% of the DUT resources.

Table 1 below shows the results for proton beam tests performed on Test circuits 1 to 7:

TABLE 1
Results for proton beam tests on Test circuits 1 to 7

| | Proton | Number | SEU cross- | SEU cross- |
|---|---|---|---|---|
| | fluence × | of SEUs | section per | section |
| | 10⁹ | detected | circuit × 10⁻¹² | (cm²/bit) × 10⁻¹² |
| Test Circuit 1 | 6.9 | 181 | 26146 | 43 |
| Test Circuit 2 | 6.4 | 11 | 1548 | 2 |
| Test Circuit 3 | 6.7 | 1 | 148 | 0.4 |
| Test Circuit 4 | 6.7 | 4 | 397 | 3.3 |
| Test Circuit 5 | 6.7 | 1 | 147 | 1 |
| Test Circuit 6 | 6.7 | 4 | 596 | 3 |
| Test Circuit 7 | 6.4 | 6 | 929 | 3 |

Several versions of the Video Graphics Array (VGA) algorithm were also implemented on the DUT in a subsequent test run. Cameras often use the VGA method to capture photographs and display them, including the cameras aboard satellites that take images from space, and thus it has a practical application in the space environment.

The different test implementations include VGA Default comprising a VGA controller with no mitigation; VGA TMR comprising a VGA controller with local TMR of the memory elements and with the conventional majority voter; and VGA DMR comprising a VGA controller with DMR of the memory elements with its outputs connected to the SEU filter which is similar to the layout of Test circuit 7.

The VGA controller requires 5 input signals for its operation, namely red, green and blue (RGB); clock and reset. For testing, the RGB signal was kept at a logic level ‘1’. The clock of the VGA controller has to be at 25 MHz to operate correctly, which was generated by a separate control board.

Table 2 below shows the results for proton beam tests performed on these VGA test circuits:

TABLE 2
Results for proton beam tests on VGA test circuits

| | Proton | Number | SEU cross- | SEU cross- |
|---|---|---|---|---|
| | fluence × | of SEUs | section per | section |
| | 10⁹ | detected | circuit × 10⁻¹² | (cm²/bit) × 10⁻¹² |
| VGA Default | 67.7 | 158 | 2333 | 104.19 |
| VGA TMR | 30.6 | 48 | 1568 | 44.82 |
| VGA DMR | 30.6 | 11 | 303 | 10.10 |

The experiments showed promising results for the various levels of mitigation schemes implemented in the test circuits.

Test circuit 1 (400) displayed the highest cross section per bit among all test circuits. This is indeed as expected, with Test circuit 1 having 10 times the cross section per bit than its nearest rival.

It was expected that Test circuit 2 (500) would have lower cross section per bit than the unmitigated design of Test circuit 1 (400), since all latches were protected with local TMR. Nevertheless, SETs were indeed expected to propagate to the memory elements, since the user logic was not protected. Compared to Test circuit 1 (400), the results show that most SEE effects are due to particle strikes directly to the latches (502, 503, 504).

Although the user logic was protected against SETs in Test circuit 3 (600), this circuit was still vulnerable to SETs affecting the filter. However, the introduction of DMR and the SET filter (610) did indeed decrease the cross section per bit, compared to Test circuit 2 (500).

Test circuit 4 (700) would normally be expected to provide full SET and SEU protection, however, the common reset and latch signals were not protected, and an SET could still affect the latches (702, 703, 704) since it is the only source of errors together with the user 10s, located on the same FPGA bank. Regardless, Test circuit 4 (700) indeed yielded a lower cross section per bit than Test circuit 3 (600).

Test circuit 5 (800) with its global latch and reset signals triplicated served to test whether errors on the global signals had a significant effect on the cross section. Indeed, Test circuit 5 (800) yielded a sevenfold reduction in cross section at 66 MeV, compared to Test circuit 4 (700), and the second lowest overall cross section per bit, with only full global TMR having a lower cross section.

Test circuit 6 (900) displayed the lowest cross section per bit of any of the designs. Since full global TMR is the most robust mitigation scheme, this result was expected. However, the full global TMR designs generally occupies the most device resources for identical circuits. As with the other test circuits, no protected was provided for the user 10s, which is the only source of potential errors.

Test circuit 7 (1000) has a similar cross-section to Test circuit 5 (800) and 6 (900). This is expected as the SEU filter (1010) has a similar effect as the majority voter in a TMR memory formation.

With the VGA controllers, compared to the unmitigated design, the TMR implementation performed better. The VGA DMR implementation showed similar performance to the VGA TMR implementation in the presence of proton irradiation, providing a 10 times better SEU cross-section than the unmitigated controller. However, in this instance too, the global clock and clear signals as well as the user logic, and FPGA IOs were not protected. It is not surprising that the VGA DMR has a similar cross-section to the VGA TMR implementation. From the view point of the SEU inducing particles, there is no difference between the two circuits.

The invention therefore provides a circuit structure for suppressing SETs or glitches in digital electronic circuits as is evident by the experimental results, which is implemented with fewer logic gates than the previous Muller C implementation.

FIG. 11 is a flow diagram of a method of suppressing SETs or glitches in digital electronic circuits. An output of a digital electronic circuit is taken (1102) as a first input, and a redundant or duplicated output of the digital electronic circuit is taken (1104) as a second input. The first input and second input are inputted (1106) into a logical circuit structure that comprises only four two-input gates of two different kinds selected from AND, OR, NAND and NOR gates. The four two-input gates are arranged so that a final circuit output is impervious to a change in a logic level of only the first input or only the second input, and the final circuit output is equivalent to the logic level of the first and second inputs when the logic level of the first and second inputs match.

Throughout the specification and claims unless the contents requires otherwise the word ‘comprise’ or variations such as ‘comprises’ or ‘comprising’ will be understood to imply the inclusion of a stated integer or group of integers but not the exclusion of any other integer or group of integers.

1. A circuit structure for supressing single event transients (SETs) or glitches in digital electronic circuits, comprising:
a first input which receives an output of a digital electronic circuit;
a second input which receives a redundant or duplicated output of the digital electronic circuit; and
only four two-input gates of two different kinds selected from AND, OR, NAND and NOR gates, the four two-input gates being arranged so that a final circuit output is impervious to a change in a logic level of only the first input or only the second input, and the final circuit output is equivalent to the logic level of the first and second inputs when the logic level of the first and second inputs match.

2. A circuit structure as claimed in claim 1 wherein the four two-input gates consist of two AND gates and two OR gates, a first AND gate and a first OR gate both receiving as inputs the first and second inputs, the first OR gate having a first output as its output and the first AND gate having a second output as its output, a second AND gate receiving as its inputs the first output and the final output of the circuit and having a third output as its output, and a second OR gate having as its inputs the second output and third output and having the final circuit output as its output.

3. A circuit structure as claimed in claim 1 wherein the four two-input gates include three inverting gates and one non-inverting gate.

4. A circuit structure as claimed in claim 3 wherein the three inverting gates are NAND gates and the non-inverting gate is an OR gate, the OR gate receiving the first and second inputs and having a first output, a first NAND gate receiving the first and second inputs and having a second output, the second NAND gate receiving the first output and the final circuit output and having a third output, and the third NAND gate receiving the second output and the third output and having the final circuit output as its output.

5. A circuit structure as claimed in claim 3 wherein the three inverting gates are two NAND gates and one NOR gate and wherein the non-inverting gate is an OR gate, a first NAND gate and the NOR gate both receiving as inputs the first input and a final circuit output, the first NAND gate having a first output as its output and the NOR gate having a second output as its output, the OR gate receiving as inputs the second output and an inverted second input and having a third output as its output, and a second NAND gate receiving as inputs the first output and third output and having the final circuit output as its output.

6. A method of suppressing single event transients (SETs) or glitches in digital electronic circuits, comprising:
taking an output of a digital electronic circuit as a first input;
taking a redundant or duplicated output of the digital electronic circuit as a second input;
inputting the first input and second input into a logical circuit structure comprising only four two-input gates of two different kinds selected from AND, OR, NAND and NOR gates, the four two-input gates being arranged so that a final circuit output is impervious to a change in a logic level of only the first input or only the second input, and the final circuit output is equivalent to the logic level of the first and second inputs when the logic level of the first and second inputs match.

7. A method as claimed in claim 6 wherein the step of inputting the first input and second input into a logical circuit structure comprising only four two-input gates includes:
inputting the first and second inputs into a first AND gate;
inputting the first and second inputs into a first OR gate;
taking an output of the first OR gate and a final circuit output and inputting them into a second AND gate;
taking the output of the second AND gate and an output of the first OR gate and inputting them into a second OR gate; and
taking the output of the second OR gate as the final circuit output.

8. A method as claimed in claim 6 wherein the step of inputting the first input and second input into a logical circuit structure comprising only four two-input gates includes:
inputting the first and second inputs into a first NAND gate;
inputting the first and second inputs into an OR gate;
taking an output of the OR gate and a final circuit output and inputting them into a second NAND gate;
taking an output of the second NAND gate and an output of the first NAND gate and inputting them into a third NAND gate; and
taking an output of the third NAND gate as the final circuit output.

9. A method as claimed in claim 6 wherein the step of inputting the first input and second input into a logical circuit structure comprising only four two-input gates includes:
inputting the first input and the final circuit output into a NOR gate;
inputting the first input and the final circuit output into a first NAND gate;
inverting the second input;
taking the output of the NOR gate and the inverted second input and inputting them into an OR gate;
taking an output of the first NAND gate and an output of the OR gate and inputting them into a second NAND gate; and
taking the output of the second NAND gate as the final circuit output.
